(19) United States
(12) Patent Application Publication
(10) Pub. No.: US 2026/0353706 A1
(43) Pub. Date: Nov. 5, 2026

(54) SHIELDED GATE TRENCH MOSFETS WITH CLOSED CELL SHAPED STRUCTURES

(71) Applicant: Nami MOS CO., LTD., New Taipei City (TW)

(72) Inventors: Fu-Yuan HSIEH, New Taipei City (TW); Lin XU, Shanghai (CN)

(73) Assignees: Nami MOS CO., LTD., New Taipei City (TW); MOSEL VITELIC INC., Hsinchu (TW)

(21) Appl. No.: 19/194,332

(22) Filed: Apr. 30, 2025

(51) Int. Cl. H10D 30/66; H10D 62/10; H10D 64/00

(52) U.S. Cl. CPC H10D 30/668; H10D 30/665; H10D 62/127; H10D 64/117

(57) ABSTRACT

An SGT MOSFET comprises an active area, a termination area, a gate metal pad area, at least one gate metal runner and at least one row of rectangular-shaped cell trench area. Each unit cell within the active area exhibits a square-shaped structure, with a first type gate trench encircling a second type gate trench. The at least one row of rectangular-shaped cell trench area is arranged beneath the at least one gate metal runner for shielded gate electrode and gate electrode contacts. The termination area includes at least one edge termination trench surrounding outer periphery of the active area but not the gate metal pad aera.

### FIELD OF THE INVENTION

This invention generally relates to a unit cell structure of a power semiconductor device that has two types of gate trenches. More particularly, it relates to integrating a first trench Metal Oxide Semiconductor Field Effect Transistor (MOSFET) with a Super Barrier Rectifier (SBR) to achieve a lower on-resistance and a less switching loss. Each unit cell within the active area has a square-shaped structure comprising a first type gate trench filled with a gate electrode that encircles a second type gate trench filled with a shielded gate electrode. At least one row of rectangular cell trench area is vertically arranged beneath the at least one gate metal runner for the contacts of the shielded gate electrode and the gate electrode. The termination area comprises at least one edge termination trench that has a step trench structure and surrounds the outer periphery of the active area.

The power semiconductor device exhibits an improved safe operation area (SOA) performance. In each unit cell, at least two different threshold voltages are achieved by forming at least one short channel implantation (SCI) region along at least one sidewall of the first type gate trench.

### BACKGROUND OF THE INVENTION

Compared with conventional trench MOSFETs, Shielded Gate Trench (SGT) MOSFETs are more attractive due to a lower specific drain-source resistance (Rsp) and an improved overall efficiency in most applications without compromising ruggedness of the device as a result of the existence of the oxide charge balance (OCB) regions formed between the two adjacent deep trenches. However, wafer warpage becomes a serious issue for the SGT MOSFETs with a stripe shaped deep trench when wafer diameter increases or breakdown voltage increases. The main reasons for the rise in the wafer warpage are the increasing depth of deep trenches and the increasing thickness of field oxide, as the breakdown voltage and wafer diameter increase. When the wafer warpage exceeds a critical value, errors in vacuum absorption or wafer transportation may occur in some equipment, and the wafers cannot be processed anymore. Moreover, the increasing field oxide thickness occupies a large space in the unit cell region, resulting in a high specific on-resistance.

Moreover, a parasitic PIN body diode of the SGT MOSFET deteriorates reverse recovery characteristics. As a result, various irradiations and Platinum diffusion techniques are normally used to reduce reverse recovery time Trr of the parasitic PIN diode. However, high leakage current between drain and source, and negative temperature coefficient in Breakdown voltage issues are observed at high temperature applications.

Besides, there is a trade-off between the efficiency and the safe operating area (SOA) performance in the design of power semiconductor devices. The SOA indicates the voltage and current conditions under which the device can operate without self-damage.

Therefore, there is still a need in the art of the semiconductor power device, particularly for the SGT MOSFET design, to provide a novel cell structure and device configuration that would resolve design limitations and improve device performance.

### SUMMARY OF THE INVENTION

The present invention provides a trench MOSFET having two types of gate trenches, integrated with a super barrier rectifier (SBR) functioning as a MOS-channel diode. It has a gate electrode disposed in a first type gate trench and a shielded gate electrode in a second type gate trench with a one-step trench structure to prevent a parasitic diode in the trench MOSFET from turning on, thereby reducing the switching loss. The integrated SBR creates a low potential barrier for the majority carriers in the MOS channel. This barrier can be adjusted by means of gate oxide thickness, body doping concentration, and channel length. A first type short channel implant (SCI1) region surrounding an upper portion of the second type gate trench is formed, wherein the SCI1 region is formed by Arsenic or Phosphorus angle implantation along sidewalls of an upper portion of the second type gate trench, and having a doping concentration higher than that of the epitaxial layer. The body dose and channel length along the SCI1 region are thereby reduced. The SBR has a lower forward voltage Vf and a lower reverse leakage current Ir than the Schottky Barrier Diode (SBD). Moreover, the SBR exhibits a better and more reliable performance at elevated temperatures than the SBD.

Moreover, this invention discloses a novel way to design at least one gate metal runner without interfering with the formation of shielded gate contacts. At least one row of rectangular-shaped cell trench area is arranged beneath the at least one gate metal runner for shielded gate electrode and gate electrode contacts. Gate electrodes connect to the at least one gate metal runner through gate contact trenches disposed between the two adjacent rectangular-shaped shielded gate electrodes in the at least one row of rectangular-shaped cell trench area.

The present invention also discloses a simple method to improve safe operating area (SOA) performance of the trench MOSFET with formation of at least two different threshold voltage regions in each unit cell including a low threshold voltage and a high threshold voltage regions, comprising a second type short channel implant (SCI2) region formed along the at least one sidewall of the first type gate trench for the low voltage threshold region formation; for a given gate voltage, formation of a low threshold voltage channel along the SCI2 region improves SOA by enabling current to flow through a channel of the low threshold voltage region first, instead of through all channels at the same time when the first gate electrode is turned on. The high threshold voltage region will be turned on when the gate voltage is increased.

These and other objects and advantages of the present invention will no doubt become obvious to those of ordinary skill in the art after having read the following detailed description of the preferred embodiment, which is illustrated in the various drawing figures.

### BRIEF DESCRIPTION OF THE DRAWINGS

The accompanying drawings, which are included to provide a further understanding of the invention and are incorporated in and constitute a part of this specification, illustrate exemplary embodiments of the invention and together with the description to explain the principles of the invention. In the drawings:

FIG. 1 is a simplified top view of a preferred embodiment for an SGT MOSFET according to the present invention.

FIG. 2A is a detailed top view of the preferred embodiment for an SGT MOSFET of FIG. 1 with square closed cells layout according to the present invention.

FIG. 2B is another detailed top view of the preferred embodiment for an SGT MOSFET of FIG. 1 with rectangular closed cells layout according to the present invention.

FIG. 2C is a cross-sectional view showing a preferred A1-A1′ cross section of FIG. 2A comprising two types of gate trenches with a single epitaxial layer, wherein the second type gate trench has a one-step gate trench structure according to the present invention.

FIG. 3A is another detailed top view of the preferred embodiment for an SGT MOSFET of FIG. 1 according to the present invention.

FIG. 3B is another detailed top view of the preferred embodiment for an SGT MOSFET of FIG. 1 according to the present invention.

FIG. 3C is a cross-sectional view showing a preferred B1-B1′/C1-C1′ cross section of FIG. 3A/FIG. 3B comprising two types of gate trenches with a single epitaxial layer, wherein the second type gate trench has a one-step gate trench structure according to the present invention.

FIG. 3D is a cross-sectional view showing another preferred B1-B1′/C1-C1′ cross section of FIG. 3A/FIG. 3B with two stepped epitaxial layers, wherein the doping concentration variations of the N type epitaxial layer as grown are depicted along the vertical direction according to the present invention.

FIG. 3E is a cross-sectional view showing another preferred B1-B1′/C1-C1′ cross section of FIG. 3A/FIG. 3B with multiple stepped epitaxial (MSE) layers, wherein the doping concentration variations of the N type epitaxial layer as grown are depicted along the vertical direction according to the present invention.

FIG. 3F is a cross-sectional view showing another preferred B1-B1′/C1-C1′ cross section of FIG. 3A/FIG. 3B with MSE layers, wherein the doping concentration variations of the N type epitaxial layer as grown are depicted along the vertical direction according to the present invention.

FIG. 4A is another detailed top view of the preferred embodiment for an SGT MOSFET of FIG. 1 according to the present invention.

FIG. 4B is a cross-sectional view showing a preferred C2-C2′ cross section of FIG. 4A comprising two types of gate trenches with a single epitaxial layer, wherein the second type gate trench has a one-step gate trench structure according to the present invention.

FIG. 5A is another detailed top view of the preferred embodiment for an SGT MOSFET of FIG. 1 according to the present invention.

FIG. 5B is a cross-sectional view showing a preferred C3-C3′ cross section of FIG. 5A comprising two types of gate trenches with a single epitaxial layer, wherein the second type gate trench has a one-step gate trench structure according to the present invention.

FIG. 6A is another detailed top view of the preferred embodiment for an SGT MOSFET of FIG. 1 comprising a trench MOSFET integrated with a SBR as a MOS-channel diode with square closed cells layout with square closed cells layout according to the present invention.

FIG. 6B is a cross-sectional view showing a preferred A2X-A2X′ cross section of FIG. 6A comprising a SiC MOSFET and a SiC SBR integrated in each unit cell, wherein the second type gate trench has a one-step gate trench structure according to the present invention.

FIG. 6C is a cross-sectional view showing a preferred A2Y-A2Y′ cross section of FIG. 6A comprising a SiC MOSFET and a SiC SBR integrated in each unit cell, wherein the second type gate trench has a one-step gate trench structure according to the present invention.

FIG. 7 is another detailed top view of a preferred embodiment for an SGT MOSFET of FIG. 1 comprising a trench MOSFET integrated with a SBR as a MOS-channel diode with square closed cells layout according to the present invention.

FIG. 8A is a cross-sectional view showing a preferred A3X-A3X′ cross section of FIG. 7 comprising a SiC MOSFET and a SiC SBR integrated in each unit cell, wherein the second type gate trench has a one-step gate trench structure according to the present invention.

FIG. 8B is a cross-sectional view showing a preferred A3Y-A3Y′ cross section of FIG. 7 comprising a SiC MOSFET and a SiC SBR integrated in each unit cell, wherein the second type gate trench has a one-step gate trench structure according to the present invention.

FIG. 9A is another cross-sectional view showing a preferred A3X-A3X′ cross section of FIG. 7 comprising a SiC MOSFET and a SiC SBR integrated in each unit cell, wherein the second type gate trench has a one-step gate trench structure according to the present invention.

FIG. 9B is another cross-sectional view showing a preferred A3Y-A3Y′ cross section of FIG. 7 comprising a SiC MOSFET and a SiC SBR integrated in each unit cell, wherein the second type gate trench has a one-step gate trench structure according to the present invention.

FIG. 10A is another cross-sectional view showing a preferred C3-C3′ cross section of FIG. 5A comprising a SiC MOSFET and a SiC SBR integrated in each unit cell, wherein the second type gate trench has a one-step gate trench structure according to the present invention.

FIG. 10B is another cross-sectional view showing a preferred C3-C3′ cross section of FIG. 5A comprising a SiC MOSFET and a SiC SBR integrated in each unit cell, wherein the second type gate trench has a one-step gate trench structure according to the present invention.

FIG. 10C is another cross-sectional view showing a preferred C3-C3′ cross section of FIG. 5A comprising a SiC MOSFET and a SiC SBR integrated in each unit cell, wherein the second type gate trench has a one-step gate trench structure according to the present invention.

### DETAILED DESCRIPTION OF THE EMBODIMENTS

In the following Detailed Description, reference is made to the accompanying drawings, which forms a part thereof, and in which is shown by way of illustration specific embodiments in which the invention may be practiced. In this regard, directional terminology, such as “top”, “bottom”, “front”, “back”, etc., is used with reference to the orientation of the Figure(s) being described. Because components of embodiments can be positioned in a number of different orientations, the directional terminology is used for purpose of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims. It is to be understood that the features of the various exemplary embodiments described herein may be combined with each other, unless specifically noted otherwise.

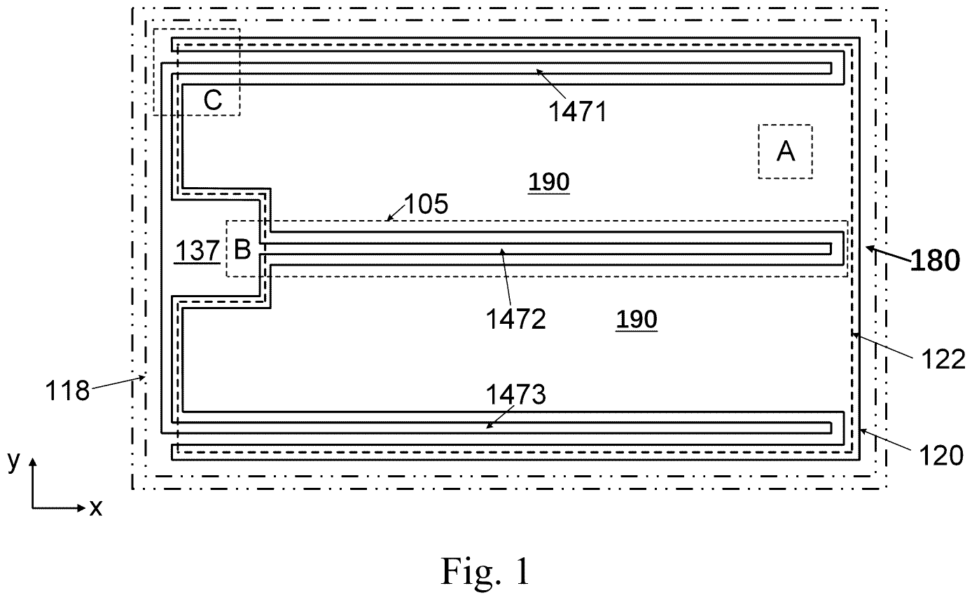

Please refer to FIG. 1 for a simplified top view of a preferred embodiment for an SGT semiconductor power device according to the present invention. The SGT semiconductor power device comprises an active area 190 wherein has a plurality of closed unit cells, a termination area 180, a gate metal pad area 137, a rectangular-shaped cell trench area 105 located in the vicinity of the middle of the source metal 120 and three gate metal runners along a first axis (the X reference direction) comprising a top edge gate metal runner 1471, a central gate metal runner 1472 and a bottom edge gate metal runner 1473 connecting the gate electrodes to the gate metal pad area 137. A 1^{st} edge termination trench 122 and a channel stop metal 118 are formed in the termination area 180 surrounding the outer periphery of the active area. However, the 1^{st} edge termination 122 does not surround the gate metal pad area.

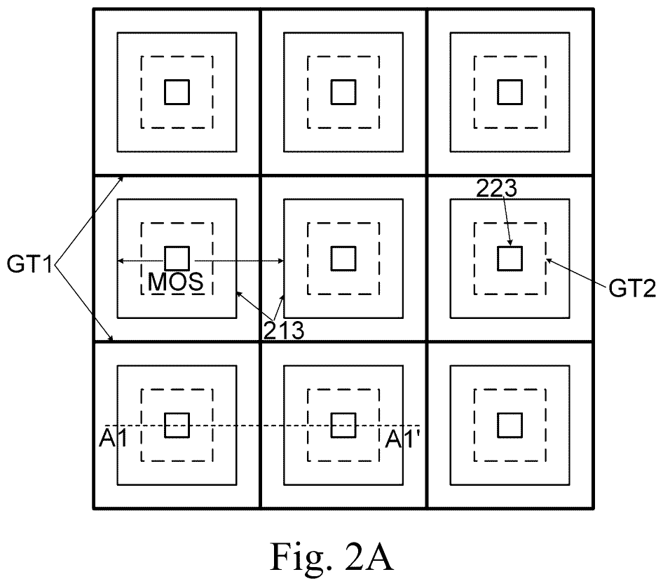

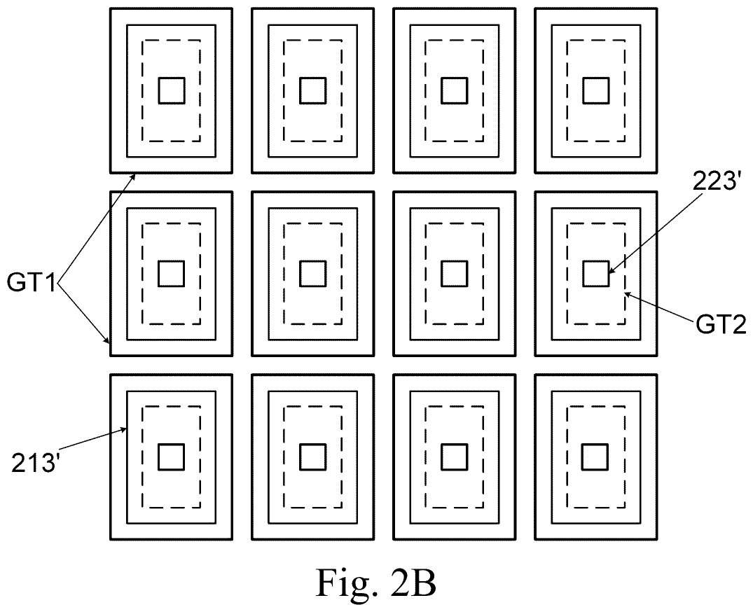

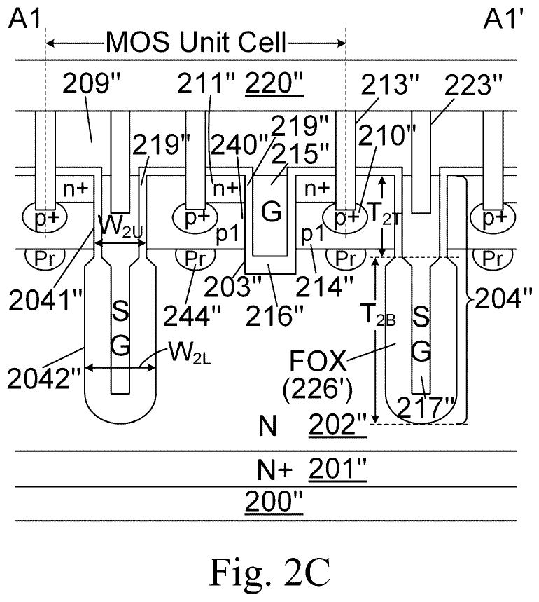

Please refer to FIG. 2A for a detailed top view of a preferred embodiment for an SGT MOSFET of FIG. 1 with square closed cells layout comprising a plurality of unit cells with each unit cell comprising two types of gate trenches. Each of the unit cells has a first type gate trench (GT1, as illustrated) with a square shape surrounds a second type gate trench (GT2, as illustrated). The GT2 has a square shape surrounding a shielded gate contact trench 223. Moreover, a source contact trench 213 with a square shape is formed between the GT1 and the GT2, and a MOS unit cell region is formed between the source contact trenches 213 of the two adjacent unit cells.

Please refer to FIG. 2B for another detailed top view of a preferred embodiment for an SGT MOSFET of FIG. 1 comprising a plurality of unit cells with each unit cell comprising two types of gate trenches. The power device has a similar structure to FIG. 2A, except that the closed cell structure in the present invention has a rectangular shape.

Please refer to FIG. 2C for a cross-sectional view showing a preferred embodiment along A1-A1′ line of FIG. 2A with a single epitaxial layer according to the present invention. The preferred embodiment comprises an N-channel SGT MOSFET formed in an N type epitaxial layer 202″ onto an N+ substrate 201″ coated with a back metal 200″ on rear side as a drain metal, wherein the power device in the present invention comprises two types of gate trenches in each MOS unit cell. Inside the N type epitaxial layer 202″, a plurality of first type gate trenches 203″ and second type gate trenches 204″ are formed vertically downward from a top surface of the N type epitaxial layer 202″ and not reaching the common interface between the N type epitaxial layer 202″ and the N+ substrate 201″, wherein the second type gate trench 204″ has a trench depth deeper than that of the first type gate trench 203″. Inside each of the first type gate trenches 203″, a gate electrode 215″ (G, as illustrated) is disposed in an upper portion and surrounded with a bottom oxide 216″ on a bottom of the first type gate trenches 203″, and with a first gate oxide (GOX1) 219″ on sidewalls of the first type gate trenches 203″, wherein the bottom oxide 216″ has a greater thickness than the GOX1 219″. Each of the second type gate trenches 204″ has a one-step gate trench structure comprising a second top gate trench 2041″ with a trench depth T_{2U} and a second bottom gate trench 2042″ with a trench depth T_{2L}, wherein the second top gate trench 2041″ is above the second bottom gate trench 2042″ with a trench width W_{2U} less than a trench width W_{2L} of the second bottom gate trench 2042″. A shielded gate electrode (SG, as illustrated) 217″ is formed in each of the second type gate trenches 204″ and surrounded with a first insulating film (FOX, as illustrated) 226″ on a bottom region and along sidewalls of the second bottom gate trench 2042″ and with the GOX1 219′ along sidewalls of the second top gate trench 2041″, wherein the FOX 226″ has a thickness greater than that of the GOX1 219″. The FOX 226″ is formed by Local Oxidation of Silicon (LOCOS). During the LOCOS process, sidewalls of the second top gate trench 2041″ are padded with either a silicon nitride layer or a two-layer stack of silicon nitride and silicon oxide to prevent the sidewalls from oxidation. Between the first type gate trench 203″ and the second type gate trench 204″, a first p (p1, as illustrated) body region 214″ with an n+ source region 211″ thereon is extending at a top surface of the N type epitaxial layer 202″ and surrounding the gate electrode 215″ padded by the GOX1 219″, wherein a p+ body contact region 210″ is formed below the n+ source regions 211″ in the p1 body regions 214″ to reduce the body contact resistance. A first channel region 240″ of the MOSFET is formed in the p1 body region 214″ along sidewalls of the first type gate trench 203″ connecting to the first source region 211″. An interlayer dielectric film 209″ is stacked on the epitaxial layer 202″, and a source metal 220″ is formed onto the interlayer dielectric film 209″. The p1 regions 214″ and the first n+ source regions 211″, and the SG 217″ are shorted to the source metal 220″ through a plurality of source contact trenches 213″ and shielded gate contact trenches 223″, respectively, wherein the source contact trenches 213″ and shielded gate contact trenches 223″ are filled with contact metal plugs and metal barriers, and the source contact trenches 213″ are surrounded by the p+ heavily doped regions 210″ around bottoms underneath the first n+ source regions 211″. According to this invention, a p type gate oxide electric field reducing (Pr, as illustrated) regions 244″ are formed adjoining lower surfaces of the p1 body regions 214″ and being apart from the first type and second type gate trenches 203″ and 204″.

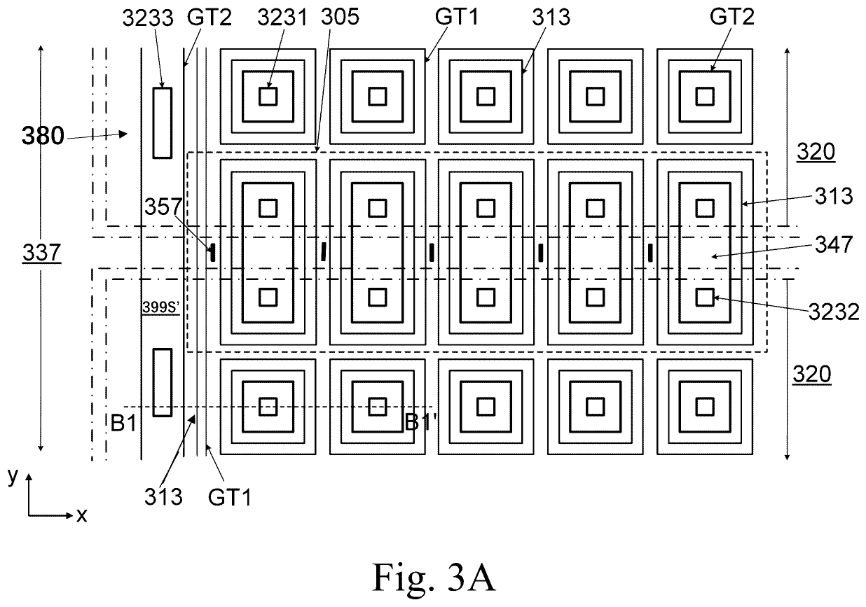

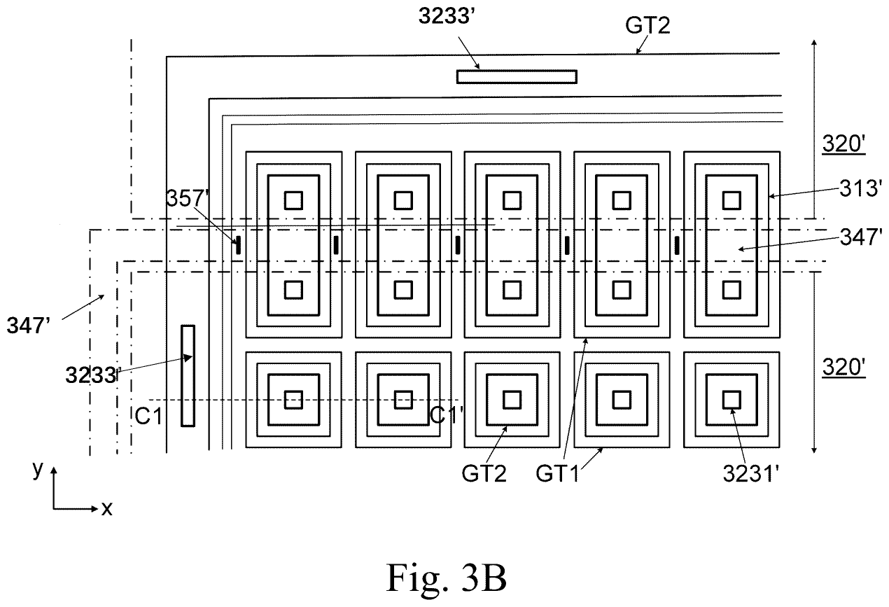

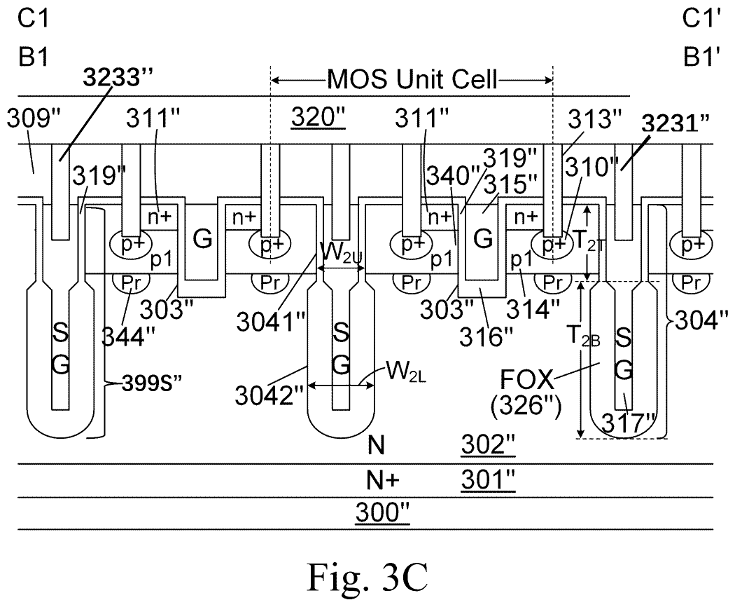

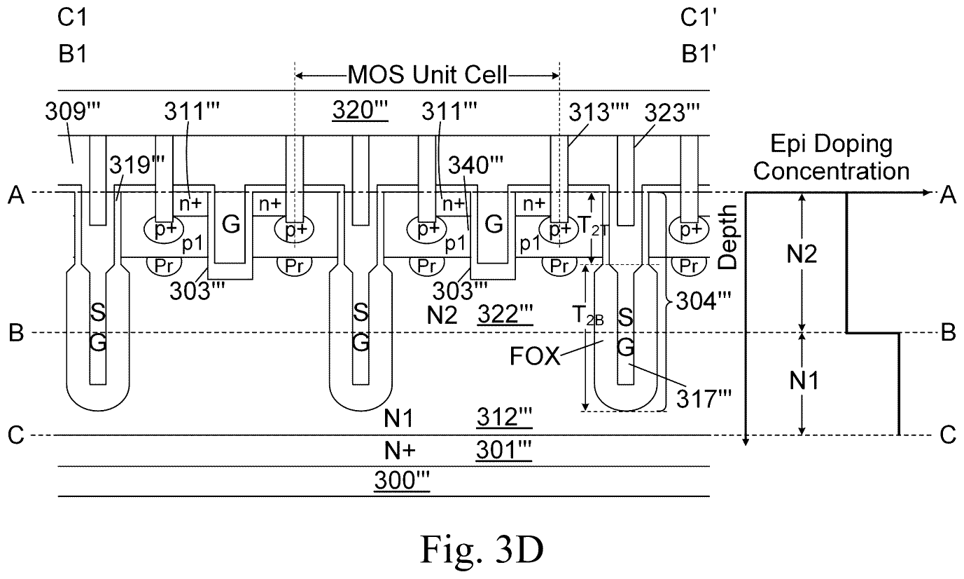

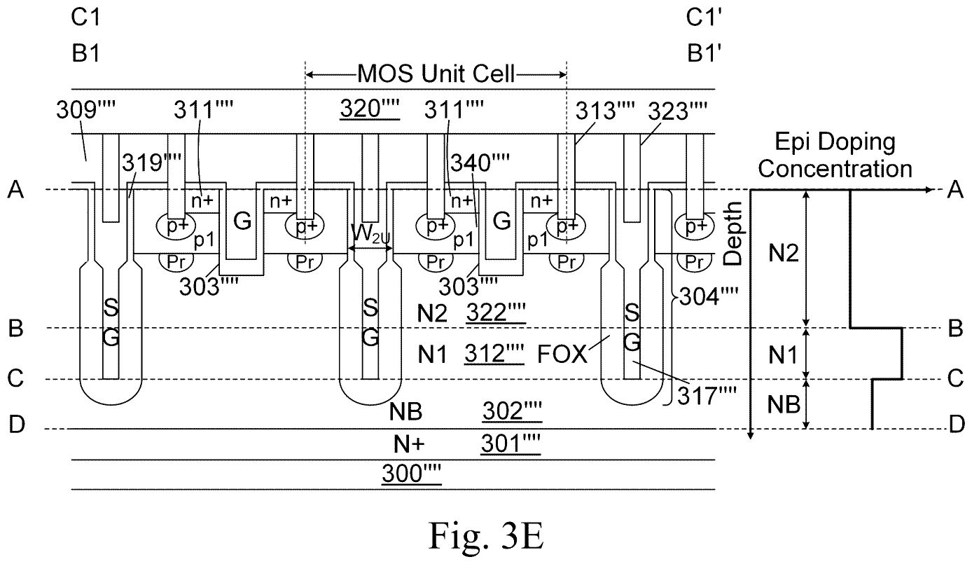

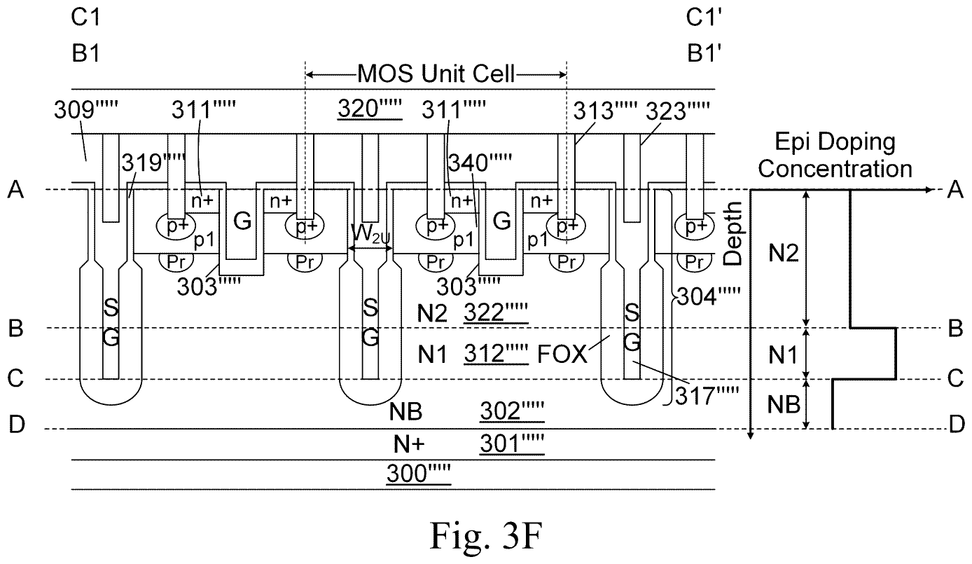

Please refer to FIG. 3A for another detailed top view of a preferred embodiment in the center portion of B area of an SGT MOSFET of FIG. 1 according to the present invention, wherein the SGT semiconductor power device comprises an active area, a termination area 380, a gate metal pad area 337, a central gate metal runner 347 located in the vicinity of the middle of the source metal 320 having a plurality of gate metal contact trenches 357 underneath, and a rectangular-shaped cell trench area 305. In a top portion of the active area, each unit cell exhibits a square-shaped structure with a first type gate trench GT1 encircling a second type gate trench GT2 surrounding a first type shielded gate (SG) contact trench 3231, with a depth greater than that of the GT1, and a square-shaped source contact trench 313 is positioned between the GT1 and the GT2. According the present invention, a rectangular-shaped cell trench area 305 horizontally extending from the gate metal pad 337 to right-hand side along a first axis is arranged beneath the gate metal runner 347. The rectangular-shape cell trench area is specially designed for the connections of second type SG contact trenches 3232 with the source metal 320, and gate metal contact trenches 357 with the gate metal runner 347, respectively. In this rectangular-shaped cell trench area 305, the GT1 has a shorter length along the first axis (the X reference direction) than along a second axis (the Y reference direction) which is perpendicular to the first axis (the X reference direction). A stripe-shaped send type gate trench 399 is located in the left-hand side of FIG. 3A as a termination trench filled with a shielded gate electrode for BV sustaining.

Please refer to FIG. 3B for another detailed top view of a preferred embodiment in the left-top corner C area of an SGT MOSFET of FIG. 1 according to the present invention, wherein the SGT semiconductor power device comprises an active area, a termination area, a central gate metal runner 347′ located in the vicinity of the middle of the source metal 320′ having a plurality of gate metal contact trenches 357′ underneath.

Please refer to FIG. 3C for a cross-sectional view showing a preferred embodiment along B1-B1′/C1-C1′ line of FIG. 3A/FIG. 3B with a single epitaxial layer according to the present invention. The N-channel trenched semiconductor power device has a similar structure to FIG. 2C, except that an additional second type gate trenches 304″ formed in the left-hand side termination area as a trench field plate with a SG contact trench 3233″ connecting with source metal 320″ in the present invention.

Please refer to FIG. 3D for a cross-sectional view showing a preferred embodiment along B1-B1′/C1-C1′ line of FIG. 3A/FIG. 3B with a new and improved device structure having two stepped epitaxial layers wherein the doping concentration variations are depicted along the vertical direction according to the present invention. The N-channel trenched semiconductor power device has a similar structure to FIG. 3C, except that, the N type epitaxial layer in the present invention comprises two stepped epitaxial layers of different doping concentration including a bottom 1^{st} epitaxial layer (N1, as illustrated between B-B and C-C lines) 312′″ with a doping concentration D1 and a top 2^{nd} epitaxial layer (N2, as illustrated between A-A and B-B lines) 322′″ with a doping concentration D2, wherein D2<D1, to further reduce the specific on-resistance.

Please refer to FIG. 3E for a cross-sectional view showing a preferred embodiment along B1-B1′/C1-C1′ line of FIG. 3A/FIG. 3B with a new and improved device structure having three stepped epitaxial layers wherein the doping concentration variations are depicted along the vertical direction according to the present invention. The N-channel trenched semiconductor power device has a similar structure to FIG. 3D, except that, the present invention further comprises a buffer epitaxial layer (NB, as illustrated) 302″″ between a bottom of the shielded gate electrode (SG, as illustrated) 317″″ and the N+ substrate 301″″ with a doping concentration DB, wherein D2<DB<D1.

Please refer to FIG. 3F for a cross-sectional view showing a preferred embodiment along B1-B1′/C1-C1′ line of FIG. 3A/FIG. 3B with a new and improved device structure having three stepped epitaxial layers wherein the doping concentration variations are depicted along the vertical direction according to the present invention. The N-channel trenched semiconductor power device has a similar structure to FIG. 3D, except that, the present invention further comprises a buffer epitaxial layer (NB, as illustrated) 302″″′ between a bottom of the shielded gate electrode (SG, as illustrated) 317″″′ and the N+ substrate 301″″′ with a doping concentration DB, wherein DB<D2<D1.

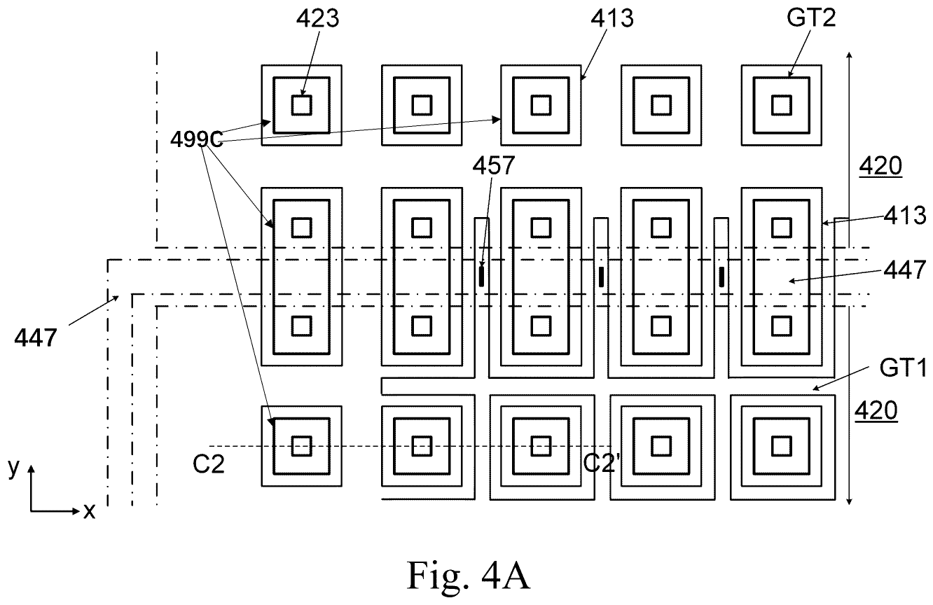

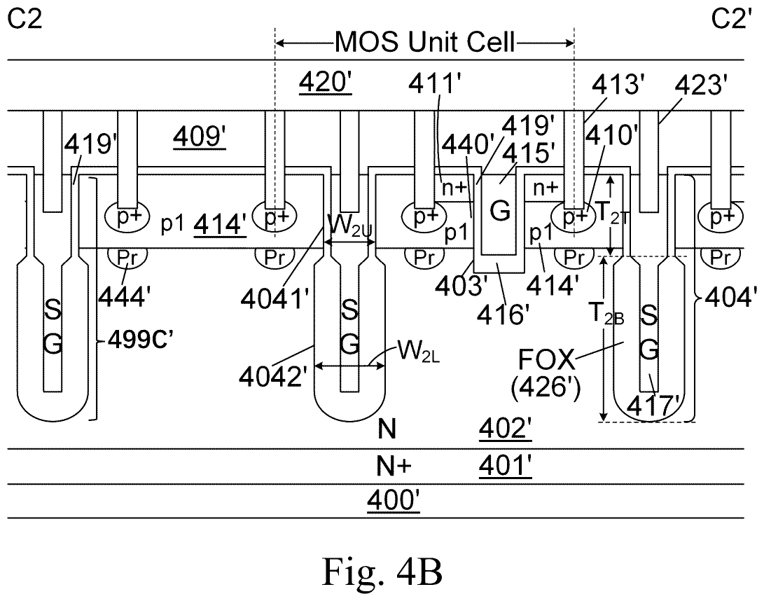

Please refer to FIG. 4A for another detailed top view of a preferred embodiment for an SGT MOSFET of FIG. 1 according to the present invention, wherein the SGT semiconductor power device comprises an active area, a termination area, and a central gate metal runner 447 located in the vicinity of the middle of the source metal 420 having a plurality of gate metal contact trenches 457 underneath. The present invention has a similar structure to FIG. 3A, except that the termination trench 499C is not stripe shape but composed of multiple closed cells filled with shielded gate electrodes for BV sustaining.

Please refer to FIG. 4B for a cross-sectional view showing a preferred embodiment along C2-C2′ line of FIG. 4A with a single epitaxial layer according to the present invention. The N-channel trenched semiconductor power device has a similar structure to FIG. 3C, except that the first type gate trench 403′ in the present invention only exist in the MOS unit cell not near by the termination area.

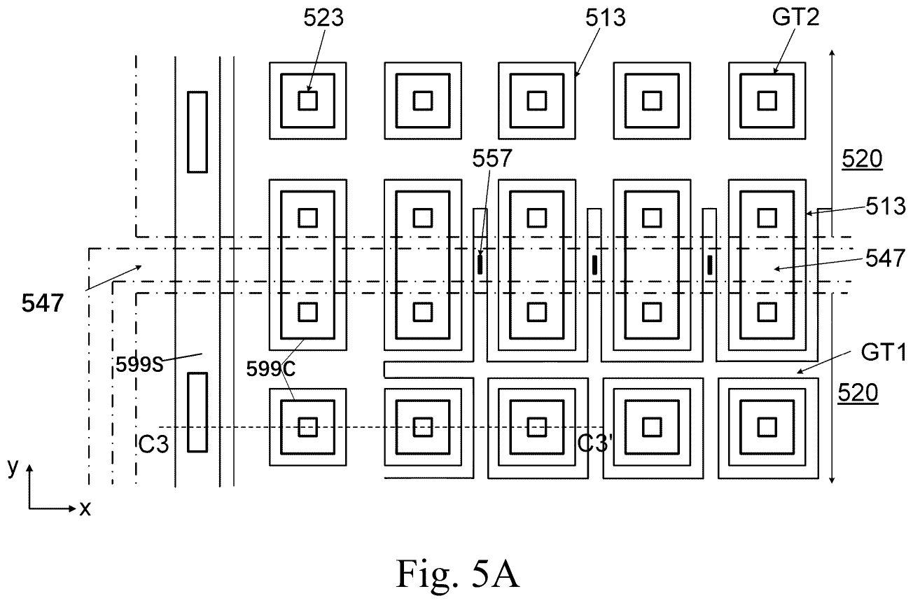

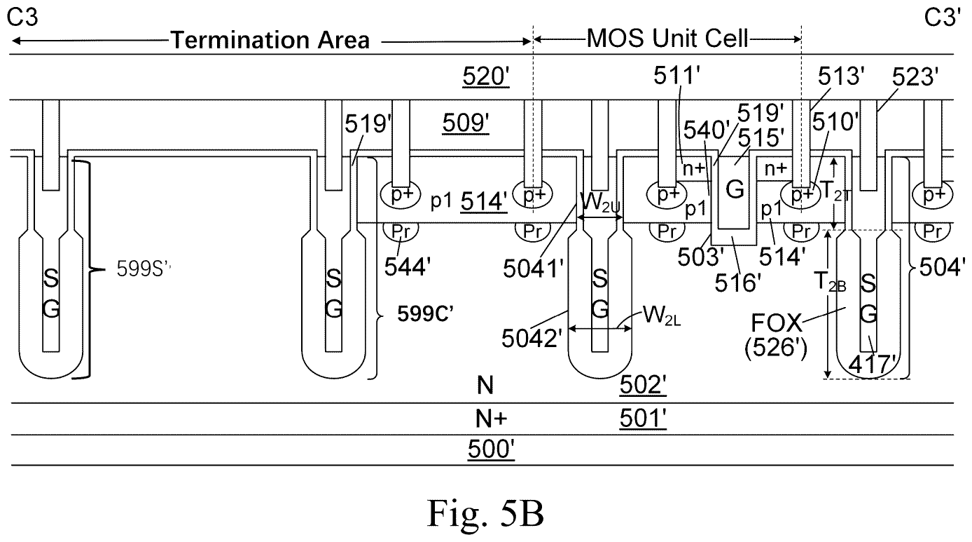

Please refer to FIG. 5A for another detailed top view of a preferred embodiment for an SGT MOSFET of FIG. 1 according to the present invention, wherein the SGT semiconductor power device comprises an active area, a termination area, and a central gate metal runner 547 located in the vicinity of the middle of the source metal 520 having a plurality of gate metal contact trenches 557 underneath. The present invention has a similar structure to FIG. 4A, except that an additional stripe shaped termination trench 599S as a second termination region surrounds a first termination region 599C in FIG. 5A.

Please refer to FIG. 5B for a cross-sectional view showing a preferred embodiment along C3-C3′ line of FIG. 5A with a single epitaxial layer according to the present invention. The N-channel trenched semiconductor power device has a similar structure to FIG. 4B, except that the present invention further comprises another second type gate trench 599S′ in the termination area. Each of the second type gate trench 599S′ and 599C′ have a trench depth equal to or deeper than that of said second type gate trench 504′ in the active area.

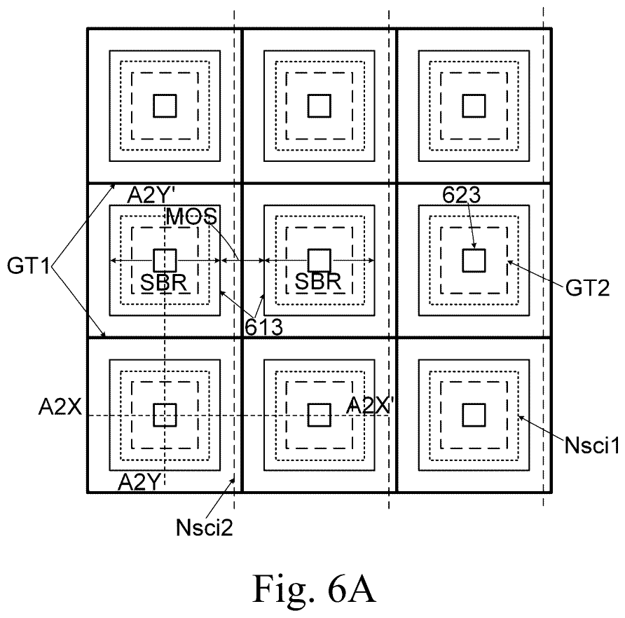

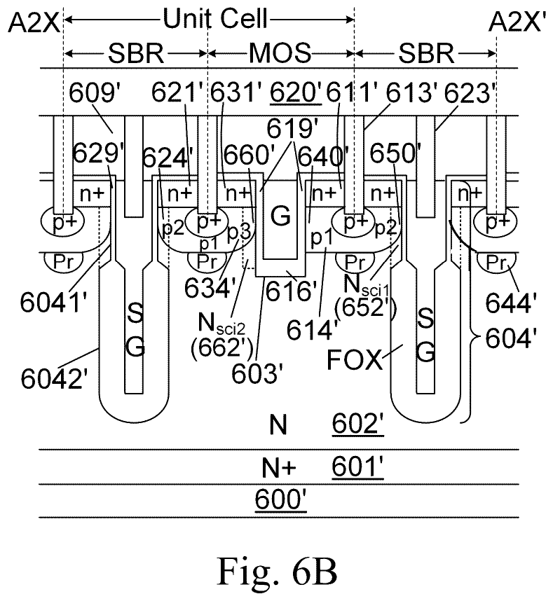

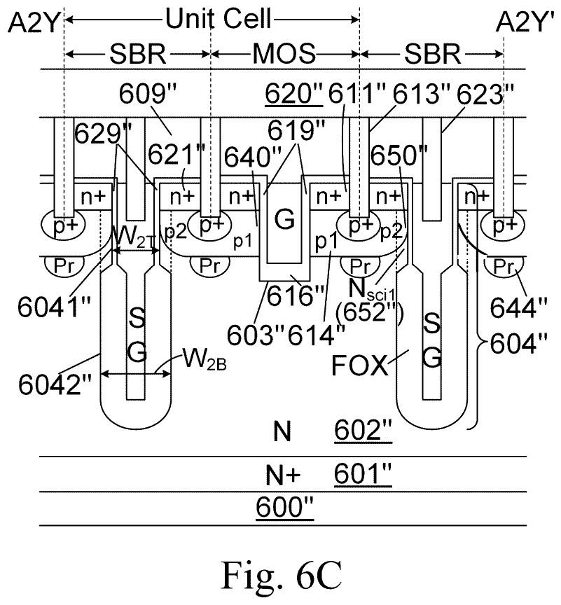

Please refer to FIG. 6A for a detailed top view of a preferred embodiment for an SGT MOSFET of FIG. 1 with square closed cells layout comprising a plurality of unit cells with each unit cell comprising two types of gate trenches. The power device has a similar structure to FIG. 2A, except that each unit cell in the present invention further comprises a super barrier rectifier (SBR, as illustrated) integrated with the MOSFET (MOS, as illustrated), and the SBR comprises a shielded gate contact 623 and a second type gate trench (GT2, as illustrated) between the two adjacent source contact trenches 613 in each unit cell, while the MOS comprises a first type gate trench (GT1, as illustrated) between the two source contact trenches 613 of the two adjacent unit cells. According to this invention, the MOS region surrounds the SBR region, and a first type short channel implant (N_{sci1}, as illustrated) region and a second type short channel implant (N_{sci2}, as illustrated) of a first conductivity type are formed along sidewalls of the GT2 and the GT1, respectively.

Please refer to FIG. 6B for a cross-sectional view showing a preferred embodiment along A2X-A2X′ line of FIG. 6A with a single epitaxial layer according to the present invention. The N-channel trenched semiconductor power device has a similar structure to FIG. 2C, except for the different gate trench structure in the second type gate trench 604′ to form a super barrier rectifier (SBR, as illustrated) region. According to this invention, a SBR region is integrated with the first MOSFET (MOS, as illustrated) in each unit cell. The present invention in FIG. 6B further comprises a second p body (p2, as illustrated) region 624′ of a second conductivity type having a second n+ source region 621′ of a first conductivity type thereon, and a third p body (p3, as illustrated) region 634′ of a second conductivity type having a third n+ source region 631′ of a first conductivity type thereon, wherein the p2 body region 624′ and p3 body region 634′ have a doping concentration lower than that of the p1 body region 614′. A second channel region 650′ of the SBR region is thus formed in the p2 body region 624′ along sidewalls of the second top gate trench 6041′ connecting to the second n+ source region 621′, and a third channel region 660′ of the first MOSFET is thus formed in the p3 body region 634′ along sidewalls of the first type gate trench 603′ connecting to the third n+ source region 631′. The second channel region 650′ and the third channel region 660′ have a channel length shorter than that of the first channel region 640′. Moreover, an N type first short channel implant (Nsci1, as illustrated) region 652′ is formed surrounding the second channel region 650′ and an N type second short channel implant (Nsci12, as illustrated) region 662′ is formed surrounding the third channel region 660′ by Arsenic or Phosphorus angle implantation along sidewalls of the top gate trench 6041′ of the second type gate trench 604′ and along sidewalls of the first type gate trench 603′, respectively, and having a doping concentration higher than that of the N type epitaxial layer 602′ to form three different threshold voltages to improve the positive temperature coefficient for reliability assurance operated at high temperatures, wherein a threshold voltage Vₜₕ₂ of the p2 body region 624′ is lower than a threshold voltage Vₜₕ₃ of the p3 body region 634′, and a threshold voltage Vₜₕ₃ of the p3 body region 634′ is lower than a threshold voltage Vₜₕ₁ of the p1 body region 614′.

Please refer to FIG. 6C for a cross-sectional view showing a preferred embodiment along A2Y-A2Y′ line of FIG. 6A with a single epitaxial layer according to the present invention. The N-channel trenched semiconductor power device has a similar structure to FIG. 6B, except that the first MOSFET has same threshold voltage Vₜₕ₂ on two sidewalls of the first type gate trench along the A2Y-A2Y′ line.

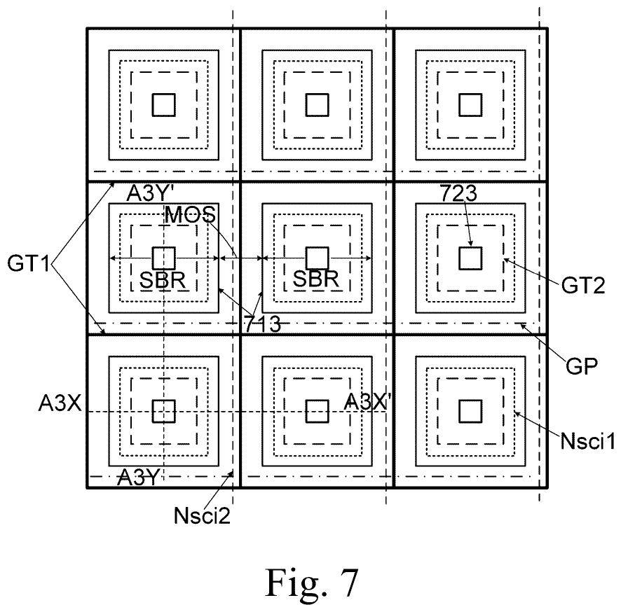

Please refer to FIG. 7 for a detailed top view of a preferred embodiment for an SGT MOSFET of FIG. 1 with square closed cells layout comprising a plurality of unit cells with each unit cell comprising two types of gate trenches. The power device has a similar structure to FIG. 6A, except that the present invention further comprises grounded P (GP, as illustrated) regions formed surrounding a portion of sidewalls of the GT1 in each unit cell.

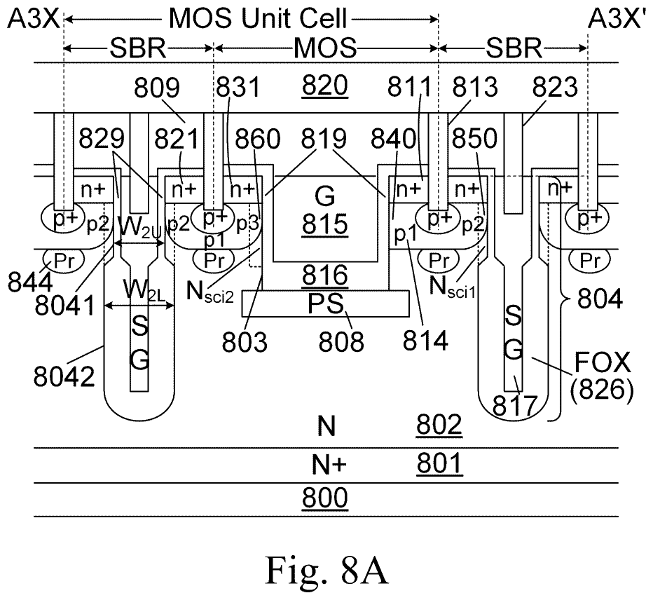

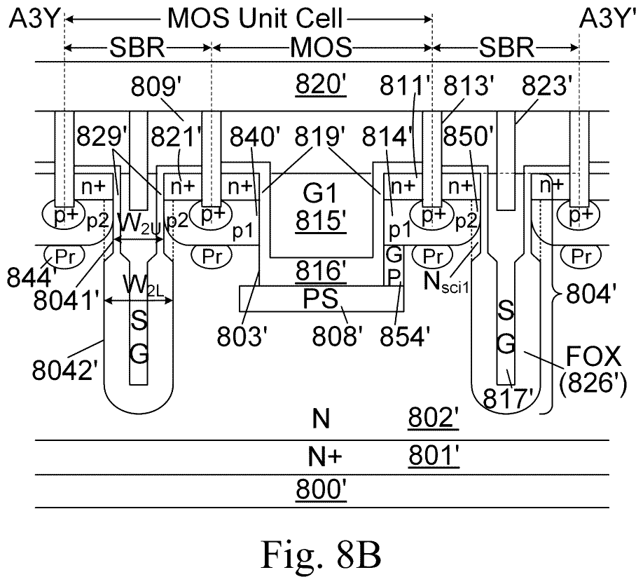

Please refer to FIG. 8A for a cross-sectional view showing a preferred embodiment along A3X-A3X′ line of FIG. 7A with a single epitaxial layer according to the present invention. The N-channel trenched semiconductor power device has a similar structure to FIG. 6B, except that the present invention further comprises a first P-shield (PS, as illustrated) region 808 formed surrounding a bottom of the first type gate trench 803 with a width greater than that of the first type gate trench 803.

Please refer to FIG. 8B for a cross-sectional view showing a preferred embodiment along A3Y-A3Y′ line of FIG. 7A with a single epitaxial layer according to the present invention. The N-channel trenched semiconductor power device has a similar structure to FIG. 6C, except that the present invention further comprises a first P-shield (PS, as illustrated) region 808′ formed surrounding a bottom of the first type gate trench 803′ with a width greater than trench width of the first type gate trench 803′, and a grounded P (GP, as illustrated) region 854′ of a second conductivity type is formed along a portion of the right-hand sidewall of the first type gate trench 803′ to ground the first PS region 808′ to a source metal 820′ through the p1 body region 814′ and the source contact trench 813′ for the gate oxide electric field reduction.

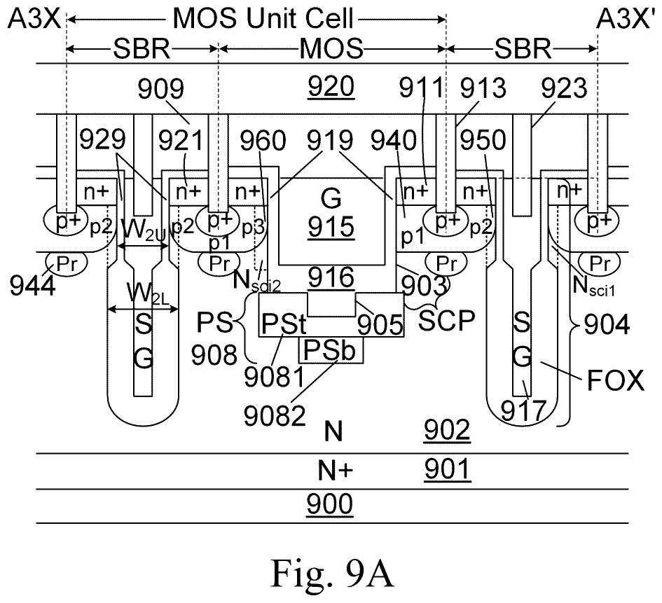

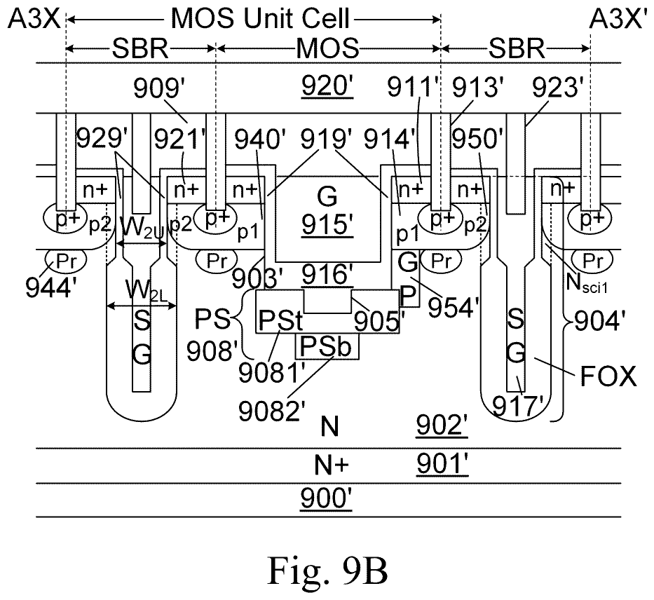

Please refer to FIG. 9A for a cross-sectional view showing another preferred embodiment along A3X-A3X′ line of FIG. 7 with a single epitaxial layer according to the present invention. The N-channel trenched semiconductor power device has a similar structure to FIG. 8A, except that the first type gate trench in the present invention has a one-step gate trench structure comprising a first top gate trench 903 and a first bottom gate trench 905, wherein the first top gate trench 903 is above the first bottom gate trench 905 with a gate width wider than that of the first bottom gate trench 905; the first gate electrode surrounded with a second insulating film 916 on a bottom region of said first top gate trench, with a thickness greater than that of the first gate oxide 940; the first bottom gate trench 905 is filled up with the second insulating film 916; Moreover, a first P-shield (PS, as illustrated) region 908 with a Y-shape structure for the gate oxide electric-field reduction is formed surrounding the first bottom gate trench 905 comprising two sub-PS regions including a first top PS (PSt, as illustrated) region 9081 and a first bottom PS (PSb, as illustrated) region 9082, wherein the PSb region 9082 is below the PSt region 9081 with a lower doping concentration than the PSt region 9081 and forms a saturation current pitching (SCP, as illustrated) region with a second P-shield region (Pr, as illustrated) 944 of a second conductivity type adjoining a lower surface of the p1 body region for the short circuit capability enhancement.

Please refer to FIG. 9B for a cross-sectional view showing another preferred embodiment along A3Y-A3Y′ line of FIG. 7 with a single epitaxial layer according to the present invention. The N-channel trenched semiconductor power device has a similar structure to FIG. 9A, except that a grounded P (GP, as illustrated) region 954′ of a second conductivity type is formed along a portion of the right-hand sidewall of the first type gate trench 903′ to ground the first PS region 908′ to a source metal 920′ through the p1 body region 814′ and the source contact trench 813′ for the gate oxide electric field reduction. The first MOSFET has a threshold voltage Vₜₕ₂ along the left-hand sidewall instead of the Vₜₕ₃.

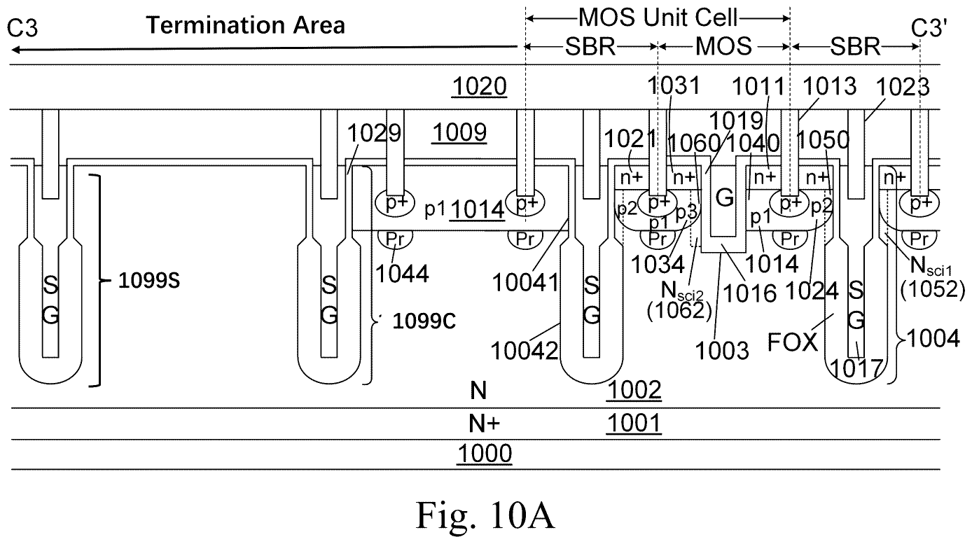

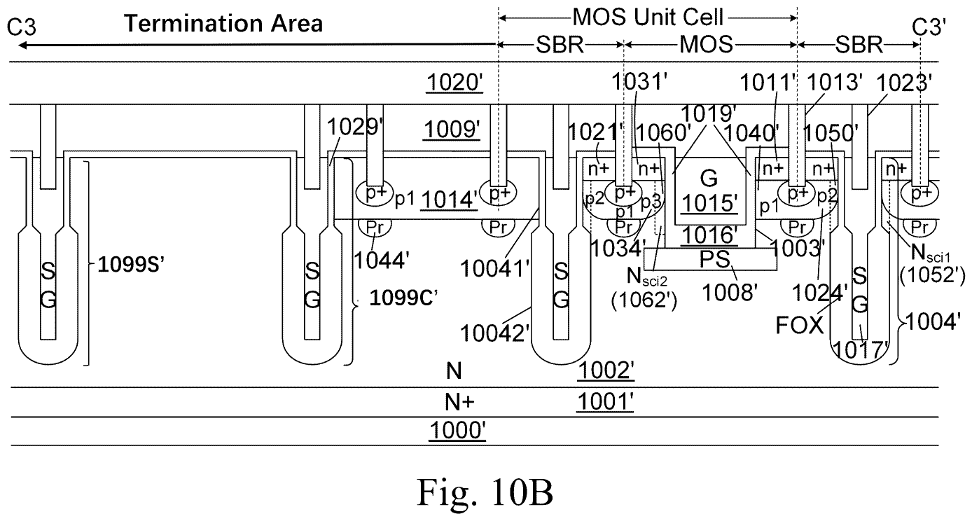

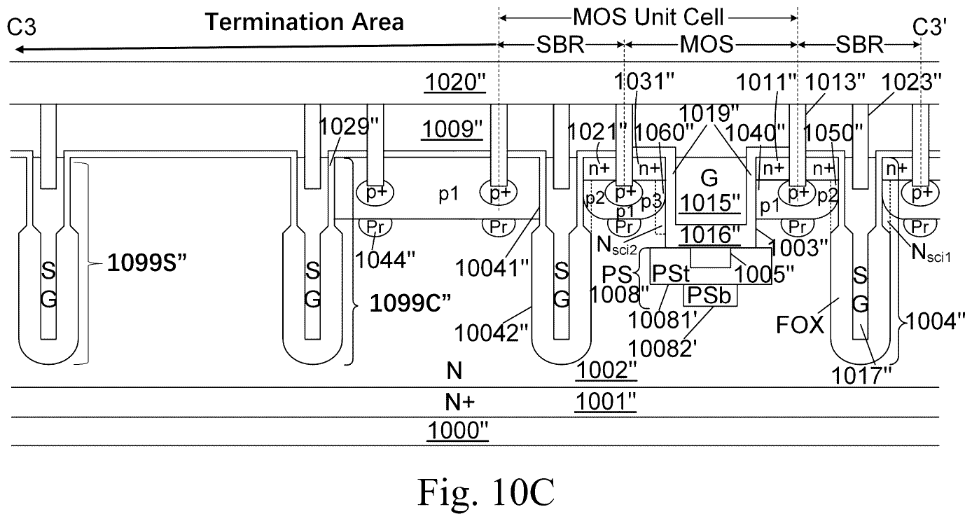

Please refer to FIG. 10A for a cross-sectional view showing another preferred embodiment along C3-C3′ line of FIG. 5A with a single epitaxial layer according to the present invention. The N-channel trenched semiconductor power device has a similar structure to FIG. 5B, except for the different gate trench structure in the second type gate trench 1004 to form a super barrier rectifier (SBR, as illustrated) region. According to this invention, a SBR region is integrated with the first MOSFET (MOS, as illustrated) in each unit cell. The present invention in FIG. 10A further comprises a second p body (p2, as illustrated) region 1024 of a second conductivity type having a second n+ source region 1021 of a first conductivity type thereon, and a third p body (p3, as illustrated) region 1034 of a second conductivity type having a third n+ source region 1031 of a first conductivity type thereon, wherein the p2 body region 1024 and p3 body region 1034 have a doping concentration lower than that of the p1 body region 1014. A second channel region 1050 of the SBR region is thus formed in the p2 body region 1024 along sidewalls of the second top gate trench 10041 connecting to the second n+ source region 1021, and a third channel region 1060 of the SBR region is thus formed in the p3 body region 1034 along sidewalls of the first type gate trench 1003 connecting to the third n+ source region 1031. The second channel region 1050 and the third channel region 1060 have a channel length shorter than that of the first channel region 1040. Moreover, an N type first short channel implant (Nsci1, as illustrated) region 1052 is formed surrounding the second channel region 1050 and an N type second short channel implant (Nsci12, as illustrated) region 1062 is formed surrounding the third channel region 1060 by Arsenic or Phosphorus angle implantation along sidewalls of the top gate trench 10041 of the second type gate trench 1004 and along sidewalls of the first type gate trench 1003, respectively, and having a doping concentration higher than that of the N type epitaxial layer 1002 to form three different threshold voltages to improve the positive temperature coefficient for reliability assurance operated at high temperatures, wherein a threshold voltage Vₜₕ₂ of the p2 body region 1024 is lower than a threshold voltage Vₜₕ₃ of the p3 body region 1034, and a threshold voltage Vₜₕ₃ of the p3 body region 1034 is lower than a threshold voltage Vₜₕ₁ of the p1 body region 1014.

Please refer to FIG. 10B for a cross-sectional view showing another preferred embodiment along C3-C3′ line of FIG. 5A with a single epitaxial layer according to the present invention. The N-channel trenched semiconductor power device has a similar structure to FIG. 10A, except that the present invention further comprises a first P-shield (PS, as illustrated) region 1008′ formed surrounding a bottom of the first type gate trench 1003′ with a width greater than that of the first type gate trench 1003′.

Please refer to FIG. 10C for a cross-sectional view showing another preferred embodiment along C3-C3′ line of FIG. 5A with a single epitaxial layer according to the present invention. The N-channel trenched semiconductor power device has a similar structure to FIG. 10B, except that the first type gate trench in the present invention has a one-step gate trench structure comprising a first top gate trench 1003″ and a first bottom gate trench 1005″, wherein the first top gate trench 1003″ is above the first bottom gate trench 1005″ with a gate width wider than that of the first bottom gate trench 1005″. Moreover, a first P-shield (PS, as illustrated) region 1008″ with a Y-shape structure for the gate oxide electric-field reduction is formed surrounding the first bottom gate trench 1005″ comprising two sub-PS regions including a first top PS (PSt, as illustrated) region 10081″ and a first bottom PS (PSb, as illustrated) region 10082″, wherein the PSb region 10082″ is below the PSt region 10081″ with a lower doping concentration than the PSt region 10081″ and forms a saturation current pitching (SCP) region with a second P-shield region (Pr, as illustrated) 1034″ of a second conductivity type adjoining a lower surface of the p1 body region for the short circuit capability enhancement.

Although the present invention has been described in terms of the presently preferred embodiments, it is to be understood that such disclosure is not to be interpreted as limiting. The embodiments described above often show N-channel devices, the embodiments can also be applied to P-channels devices by reversing the polarities of the conductivity types. Various alternations and modifications will no doubt become apparent to those skilled in the art after reading the above disclosure. Accordingly, it is intended that the appended claims be interpreted as covering all alternations and modifications as fall within the true spirit and scope of the invention.

What is claimed is:

1. A shielded gate trench (SGT) device having two types of gate trenches in each unit cell comprising:
an active area, a termination area, a gate metal pad area, at least one gate metal runner along a first axis and at least one row of rectangular-shaped cell trench area beneath said at least one gate metal runner;
an epitaxial layer of a first conductivity type on a substrate;
said each unit cell within said active area exhibiting a square-shaped structure with a first type gate trench encircling a second type gate trench; said second type gate trench having a greater depth compared to said first type gate trench;
a source contact trench with a square-shaped structure positioned between said first type gate trench and said second type gate trench;
a first body region of a second conductivity type having a first source region of said first conductivity type thereon;
a first type gate trench penetrating said first body region and said first source region and terminating within said epitaxial layer;
said second type gate trench formed in said epitaxial layer having a first type step-trench structure with a narrower trench width in an upper portion than in a lower portion of said second type gate trench; additionally, said second type gate trench is deeper than said first type gate trench;
a first gate electrode disposed in said first type gate trench and surrounded with a first gate oxide along sidewalls of said first type gate trench;
a first shielded gate electrode disposed in said second type gate trench surrounded with a first insulating film on a bottom region and along sidewalls of said lower portion of said second type gate trench, and with a second gate oxide along said upper portion of said second type gate trench; said first insulating film having a thickness greater than that of said first and second gate oxides;
a first channel region of a first Metal Oxide Semiconductor Field Effect Transistor (MOSFET) formed in said first body region along sidewalls of said first type gate trench connected to said first source region;
said first body and said first source regions, and said shielded gate electrode being shorted to a source metal through said source contact trench and a shielded gate contact trench, respectively;
said at least one row of rectangular-shaped cell trench area is specially designed to respectively connect said shielded gate contact trench with a source metal and a gate metal contact trench with said at least one gate metal runner;
in said at least one row of rectangular-shaped cell trench area, said first type gate trench has a shorter length along said first axis than along a second axis which is perpendicular to said first axis; and
said termination area including at least one termination region surrounding outer periphery of said active area.

2. The SGT device of claim 1, wherein said at least one termination region has a first termination trench with a stripe-shaped structure of said second type gate trench.

3. The SGT device of claim 1, wherein said at least one termination region has a first termination trench with a square-shaped or a rectangular-shaped structure of said second type gate trench.

4. The SGT device of claim 1, wherein said at least one termination region comprising a first termination trench with either a stripe-shaped, square or rectangular-shaped structure, and a second termination trench with a stripe-shaped structure of said surrounding outer periphery of said at least one termination region.

5. The SGT device of claim 1, wherein said at least one termination region has at least one termination trench of said second type gate trench with a trench depth equal to or deeper than that of said second type gate trench in said active area.

6. The SGT of claim 1, wherein said first insulating film is formed by Local Oxidation of Silicon (LOCOS); sidewalls of said upper portion of said second type gate trench are padded with either a silicon nitride layer or two-layer stack of silicon nitride and silicon oxide during said LOCOS process to prevent sidewalls of said upper portion of said second type gate trench from oxidation.

7. The SGT device of claim 1, further comprising a P-shield region of said second conductivity type adjoining a lower surface of said first body region.

8. The SGT device of claim 1, wherein said epitaxial comprises at least two stepped epitaxial layers of different doping concentrations including a bottom epitaxial layer with a doping concentration D1 and a top epitaxial layer above said bottom epitaxial layer with a doping concentration D2, wherein said D2<said D1.

9. The SGT device of claim 8, further comprising a buffer epitaxial layer between said substrate and said bottom epitaxial layers having a doping concentration DB, wherein said DB<said D2<said D1.

10. The SGT device of claim 8, further comprising a buffer epitaxial layer between said substrate and said bottom epitaxial layer having a doping concentration DB, wherein said D2<said DB<said D1.

11. The SGT device of claim 1, wherein said second gate oxide has a thickness less that of said first gate oxide and
said SGT device further comprising a second body region of said second conductivity type having a second source region of said first conductivity type thereon, with a doping concentration lower than that of said first body region;
a second channel region of a Super Barrier Rectifier (SBR) formed in said second body region along sidewalls of said upper portion of said second type gate trench connected to said second source region;
said first and second body regions, said first and second source regions, and said second gate electrode being shorted to said source metal through said source contact trenches. and
said SBR integrated with said first MOSFET in said each unit cell.

12. The SGT device of claim 11, further comprising a first type short channel implant (SCI1) region of said first conductivity type surrounding said second channel region, wherein said SCI1 region is formed by Arsenic or Phosphorus angle implantation along sidewalls of said upper portion of said second type gate trench, and having a doping concentration higher than that of said epitaxial layer; said second channel region has a channel length shorter than that of said first channel region.

13. The SGT device of claim 11, wherein said first gate electrode is surrounded with a second insulating layer on a bottom region of said first type gate trench; and said second insulating layer having a thickness greater than that of said first gate oxide;
a first P-shield (PS) region of said second conductivity type for gate oxide electric-field reduction disposed below said first type gate trench;
a second P-shield region of said second conductivity type adjoining a lower surface of said first body region, forming a saturation current pitching (SCP) region with said first PS region for the short circuit capability enhancement; and
at least one grounded P (GP) region of said second conductivity type surrounding a portion of sidewalls of said first type gate trench connecting with said first body region and said first PS region;

14. The SGT device of claim 11, wherein said first type gate trench having a second type step-trench structure comprising at least one step trench including a first top gate trench and a first bottom gate trench; said first top gate trench is above said first bottom gate trench, with a trench width larger than that of said first bottom gate trench;
said first gate electrode surrounded with a second insulating film on a bottom region of said first top gate trench with a thickness greater than that of said first gate oxide;
a first P-shield (PS) region of said second conductivity type for gate oxide electric-field reduction surrounding said at least one first bottom gate trench filled up with said second insulating film;
said first PS region comprising at least two sub-PS regions including a first top PS region and a first bottom PS region, wherein said first bottom PS region is below said first top PS region with a doping concentration lower than that of said top PS region;
a second PS region of said second conductivity type adjoining a lower surface of said first body region, forming a saturation current pitching (SCP) region with said first PS region for the short circuit capability enhancement; and
at least one grounded P (GP) region of said second conductivity type surrounding a portion of sidewalls of said first type gate trench connecting with said first body region and said first PS region.

15. The SGT device of claim 12, further comprising a second type short channel implant (SCI2) region of said first conductivity type formed along at least one sidewall of said first type gate trench, wherein said SCI2 region is formed by Arsenic or Phosphorus angle implantation into said epitaxial layer through said at least one sidewall of said first type gate trench, and has a doping concentration higher than that of said epitaxial layer.

16. The power device of claim 15, wherein said first MOSFET has at least two different threshold voltage channel regions in each unit cell comprising a low threshold voltage channel region and a high threshold voltage channel region formed along with and without said SCI2 region, respectively.

17. The SGT device of claim 16, wherein said low threshold voltage channel region has a threshold voltage in a range of 1 to 3 V and said high threshold voltage channel region has a threshold voltage of 3 to 6 V; and said first MOSFET has a threshold voltage in a range of 2.5 to 4.5 V.

18. A shielded gate trench (SGT) device having two types of gate trenches in each unit cell comprising:
an active area, a termination area, a gate metal pad area, at least one gate metal runner along a first axis, and at least one row of rectangular-shaped cell trench beneath said at least one gate metal runner;
an epitaxial layer of a first conductivity type on a substrate;
each unit cell within said active area exhibiting a closed-cell structure with a first type gate trench encircling a second type gate trench; said second type gate trench having a greater depth compared to said first type gate trench;
a source contact trench positioned between said first type gate trench and said second type gate trench;
a first body region of a second conductivity type having a first source region of said first conductivity type thereon;
a first type gate trench penetrating said first body region and said first source region and terminating within said epitaxial layer;
said second type gate trench formed in said epitaxial layer with a trench depth deeper than that of said first type gate trench;
a first gate electrode disposed in said first type gate trench and surrounded with a first gate oxide along sidewalls of said first type gate trench;
a first shielded gate electrode disposed in said second type gate trench surrounded with a first insulating film on a bottom region and along sidewalls of said lower portion of said second type gate trench, and with a second gate oxide along said upper portion of said second type gate trench; said first insulating film having a thickness greater than that of said first and second gate oxides;
a first channel region of a first Metal Oxide Semiconductor Field Effect Transistor (MOSFET) formed in said first body region along sidewalls of said first type gate trench connected to said first source region;
said first body and said first source regions, and said shielded gate electrode being shorted to a source metal through source contact trenches and shielded gate contact trenches, respectively;
said at least one row of rectangular-shaped cell trench area is specially designed to respectively connect said shielded gate contact trench with a source metal and a gate metal contact trench with said at least one gate metal runner;
in said at least one row of rectangular-shaped cell trench area, said first type gate trench has a shorter length along the first axis than along a second axis which is perpendicular to the first axis; and
said termination area including at least one first termination region surrounding outer periphery of said active area.

19. The SGT device of claim 18, wherein said closed cell structure is a square or rectangular shaped structure.

20. The SGT device of claim 18, wherein said second gate oxide has a thickness less that of said first gate oxide;
and said SGT device further comprising:
a second body region of said second conductivity type having a second source region of said first conductivity type thereon with a doping concentration lower than that of said first body region;
a second channel region of a Super Barrier Rectifier (SBR) formed in said second body region along sidewalls of said upper portion of said second type gate trench connected to said second source region;
said first and second body regions, said first and second source regions, and said second gate electrode being shorted to a source metal through source contacts;
said SBR is integrated with said first MOSFET in said each unit cell;
a first type short channel implant (SCI1) region of said first conductivity type surrounding said second channel region, wherein said SCI1 region is formed by Arsenic or Phosphorus angle implantation along sidewalls of said upper portion of said second type gate trench, and having a doping concentration higher than that of said epitaxial layer; said second channel region has a channel length shorter than that of said first channel region; and
a P-shield region of said second conductivity type adjoining a lower surface of said first body region.
